(19) United States
(12) Patent Application Publication
(10) Pub. No.: US 2025/0158575 A1
(43) Pub. Date: May 15, 2025

(54) Doherty Amplifier

(71) Applicant: Ampleon Netherlands B.V., Nijmegen (NL)

(72) Inventors: Waqam Hussain Riaz Ahmad Mukhtar Ahmad, Nijmegen (NL); Wasam Riaz Ahmad Mukhtar Ahmad, Nijmegen (NL)

(21) Appl. No.: 18/945,684

(22) Filed: Nov. 13, 2024

(30) Foreign Application Priority Data
Nov. 13, 2023 (NL) 2036254

(51) Int. Cl. H03F 1/02; H03F 1/56; H03F 3/24; H03F 3/60

(52) U.S. Cl. CPC H03F 1/0288; H03F 1/56; H03F 3/245; H03F 3/604

(57) ABSTRACT

Example embodiments relate to Doherty amplifiers. One example Doherty amplifier includes a main amplifier and a peak amplifier. The Doherty amplifier also includes a Doherty splitter configured for: splitting an input signal into a main signal part and a peak signal part and providing the main signal part and the peak signal part to the main amplifier and the peak amplifier, respectively. Additionally, the Doherty amplifier includes a Doherty combiner having a first input port, a second input port, and an output port. Further, the Doherty amplifier includes a non-impedance-inverting connection between an output of the main amplifier and the first input port. In addition, the Doherty amplifier includes a first impedance inverting network arranged in between an output of the peak amplifier and the second input port. Yet further, the Doherty combiner includes a second impedance inverting network and a third impedance inverting network.

### CROSS-REFERENCE TO RELATED APPLICATIONS

The present application is a non-provisional patent application claiming priority to Netherlands Patent Application No. NL 2036254, filed Nov. 13, 2023, the contents of which are hereby incorporated by reference.

### FIELD OF THE DISCLOSURE

Aspects of the present disclosure relate to a Doherty amplifier. Aspects of the present disclosure further relate to a base station for mobile communications comprising such an amplifier.

### BACKGROUND

Doherty amplifiers, or DPAs comprise a main amplifier and one or more peak amplifiers. The main amplifier is typically biased in class B, while the one or more peak amplifiers are biased in class C. A Doherty splitter is used for splitting an input RF signal into a main signal part and one or more peak signal parts and for providing these signals parts to the main amplifier and the one or more peak amplifiers, respectively. The signals amplified by the main amplifier and the one or more peak amplifiers are combined in-phase by a Doherty combiner.

A main advantage of using a DPA is the improved efficiency under power back-off. This improved efficiency is obtained using load modulation. More specifically, under power back-off conditions, the one or more peak amplifiers are switched off. As a result, the one or more peak amplifiers do not output current through the output of the DPA and a voltage at the output will therefore be lower than in the situation where current is output by the one or more peak amplifiers. The lower voltage can be translated into a smaller impedance.

The Doherty combiner of a DPA is configured to invert this impedance behavior. Put differently, the smaller impedance seen near the combining node is transformed into a higher impedance that is presented at the output of the main amplifier. Similarly, when the one or more peak amplifiers do output current through the output, the effective impedance raises, and a lower impedance is presented at the output of the main amplifier.

The use of a higher impedance at power back-off compared to the saturated mode of operation in which all amplifiers are outputting power allows better efficiencies to be obtained under power back-off. More specifically, the efficiency versus input power of a DPA typically shows a peak efficiency near saturated output power and at least one further peak efficiency under power back-off. Multiple peaks under power back-off can be obtained by using multiple peak amplifiers.

DPAs are known in two different topologies, which are both shown in FIG. 1. In the well-known topology of DPA 1A, an input signal is split by Doherty splitter 10, and the corresponding signal parts are amplified by a main amplifier 20 and a peak amplifier 30. An impedance inverter in the form of a 90 degrees transmission line with characteristic impedance Z0 is arranged in between the output of main amplifier 20 and combining node C. Here, combining node C also forms the output of DPA 1A. A load impedance ZL can be connected to combining node C. Transmission lines with impedances Z1 and Z2 are used for presenting a high impedance to combining node C at power back-off, whereas they provide an impedance match under saturated power conditions.

DPA 1B uses coupler 40 for combining the signal from main amplifier 20 and peak amplifier 30. If peak amplifier 30 is switched off, a high impedance can be seen looking into peak amplifier 30. This high impedance is transformed by the 90 degrees transmission line with characteristic impedance Z0 into an RF short presented at one port of coupler 40. When peak amplifier 30 is switched on, a phase difference exists between the signals entering at the two different input ports of coupler 40. As a result, the impedance seen by main amplifier 20 under power back-off conditions is higher than that under saturated power conditions, thereby achieving improved efficiency under power back-off conditions.

As can be observed, DPA 1B has no impedance inverter arranged in between coupler 40 and main amplifier 20. As these elements are typically realized using a 90 degrees transmission line, they tend to degrade the bandwidth of the amplifier. For this reason, DPA 1B presents an interesting topology from a bandwidth point of view. However, at the same time, realizing coupler 40 can be area-consuming, particularly for relatively low frequencies, e.g. 1 GHz.

### SUMMARY

According to an aspect of the present disclosure, a Doherty amplifier is provided that offers a less area-consuming bandwidth improvement. This Doherty amplifier comprises a main amplifier, a peak amplifier, a Doherty splitter configured for splitting an input signal into a main signal part and a peak signal part and to provide these signal parts to the main amplifier and peak amplifier, respectively. The amplifier further comprises a Doherty combiner having a first input port, a second input port, and an output port. Additionally, the amplifier comprises a non-impedance-inverting connection between an output of the main amplifier and the first input port, and a first impedance inverting network arranged in between an output of the peak amplifier and the second input port. The Doherty splitter, the non-impedance-inverting connection, and the first impedance inverting network are configured such that a signal at the first input port of the Doherty combiner and a signal at the second port of the Doherty combiner have opposite phases.

The Doherty combiner comprises a second impedance inverting network in between the first input port and the output port, and a third impedance inverting network in between the second input port and the output port, wherein the Doherty combiner is configured to add the signal amplified by the main amplifier and the signal amplified by the first amplifier in-phase at the output port.

The Applicant has found that by ensuring the 180 degrees difference, at least substantially, at the input ports of the Doherty combiner, a bandwidth improvement can be obtained although the Doherty combiner can be realized using less board space.

The second impedance inverting network may comprise a transmission line or assembly of transmission lines having a first electrical length at the operational frequency. The third impedance inverting network may comprise a transmission line or assembly of transmission lines having a second electrical length at the operational frequency. The first and second electrical lengths may differ by substantially 180 degrees at the operational frequency.

One of the second impedance inverting network and third impedance inverting network may comprise a quarter-wavelength transmission line, and the other of the second impedance inverting network and third impedance inverting network may comprise a quarter-wavelength transmission line in series with a half-wavelength transmission line.

Additionally, or alternatively, the Doherty combiner may further comprise a half-wavelength transmission line in between the first and second inputs of the Doherty combiner, wherein a center region of this half-wavelength transmission line is RF grounded. For example, an electrical length between the center region and each of the first and second input ports of the Doherty combiner may equal 90 degrees at or near the operational frequency. In this manner, an impedance at each of the first and second input ports looking towards the center region through the half-wavelength transmission line corresponds to an RF open due to the impedance inversion realized by the quarter wave sections between the center region and the first and second input ports.

The half-wavelength transmission lines and the quarter-wavelength transmission lines of the second and third impedance inverting networks may jointly form a rat-race coupler. A rat-race coupler has four ports arranged in a ring. The electrical distance, in between brackets, between these ports corresponds to p1->p2 (90), p2->p3 (90), p3->p4 (90), p4->p1 (270). In this example, port p2 can be grounded, ports p1 and p3 can be used as input ports of the Doherty combiner, and port p4 can be used as output port.

As the center region is RF grounded, it can be used for biasing the main and peak amplifiers. For example, the Doherty amplifier may comprise a biasing circuitry for providing a bias signal to the main amplifier and peak amplifier, wherein the biasing circuitry is connected to the center region of the half-wavelength transmission line arranged between the first and second inputs of the Doherty combiner.

The characteristic impedances of all the transmission lines of the second and third impedance inverting networks may all equal a same characteristic impedance. More in particular, all transmission lines of the second and third impedance inverting networks may of the same transmission line type and may have the same dimensions with the exception of length.

The first impedance inverting network may comprise a first impedance matching network connected to the output of the peak amplifier, a first quarter-wavelength transmission line, and a second quarter-wavelength transmission line, wherein the first quarter-wavelength transmission line is arranged between the first impedance matching network and the second quarter-wavelength transmission line. A combined electrical length of the first impedance inverting network may correspond to 270 degrees at or close to the operational frequency.

The peak amplifier may comprise a peak power transistor having an intrinsic drain, wherein the first impedance matching network is connected in between the intrinsic drain of the peak power transistor and the quarter-wavelength transmission line.

The non-impedance-inverting connection may comprise a second impedance matching network connected to the output of the main amplifier, and a first quarter-wavelength transmission line. A combined electrical length of the non-impedance inverting network may correspond to 180 degrees at or close to the operational frequency.

The main amplifier may comprise a first power transistor having an intrinsic drain. In this case, the second impedance matching network can be connected in between the intrinsic drain of the main power transistor and the quarter-wavelength transmission line.

The Doherty amplifier may further comprise a printed circuit board, PCB, wherein the Doherty combiner is realized on the PCB. The first and second quarter-wavelength transmission lines of the first impedance inverting network can be realized on the PCB, wherein the first impedance matching network is partially realized on the PCB. Additionally, or alternatively, the quarter-wavelength transmission line of the non-impedance-inverting connection can be realized on the PCB, wherein the second impedance matching network is partially realized on the PCB.

The main amplifier and peak amplifier can be provided as packaged devices, wherein the main amplifier and the peak amplifier are preferably provided in a single package. For example, the main amplifier and peak amplifier may each comprise a laterally diffused metal-oxide-semiconductor, LDMOS, power transistor or a Gallium Nitride based field-effect power transistor. The semiconductor dies corresponding to these power transistors can for example be mounted in a lead-frame package. In this case, the first impedance matching network may be partially formed by bondwires extending between the drain bondpad of the power transistor of the peak amplifier and the corresponding lead of the peak amplifier package. Similarly, the second impedance matching network may be partially formed by bondwires extending between the drain bondpad of the power transistor of the main amplifier and the corresponding lead of the main amplifier package.

According to a second aspect of the present disclosure, a base station for mobile telecommunications is provided that comprises the Doherty amplifier as defined above.

### BRIEF DESCRIPTION OF THE DRAWINGS

Next, aspects of the present disclosure will be described in more detail by referring to the appended drawings, wherein identical or similar components will be referred to using identical reference signs, and wherein:

FIG. 1 illustrates two known topologies for DPAs;

FIG. 2 illustrates a general embodiment of a DPA in accordance with the present disclosure;

FIG. 3 illustrates a first specific embodiment of a DPA in accordance with the present disclosure using a rat-race coupler;

FIG. 4 illustrates a first specific embodiment of a DPA in accordance with the present disclosure using transmission lines;

FIG. 5 illustrates a further specific embodiment of a DPA in accordance with the present disclosure using a rat-race coupler; and

FIG. 6 illustrates a performance of a DPA in accordance with the present disclosure compared to a known DPA.

### DETAILED DESCRIPTION

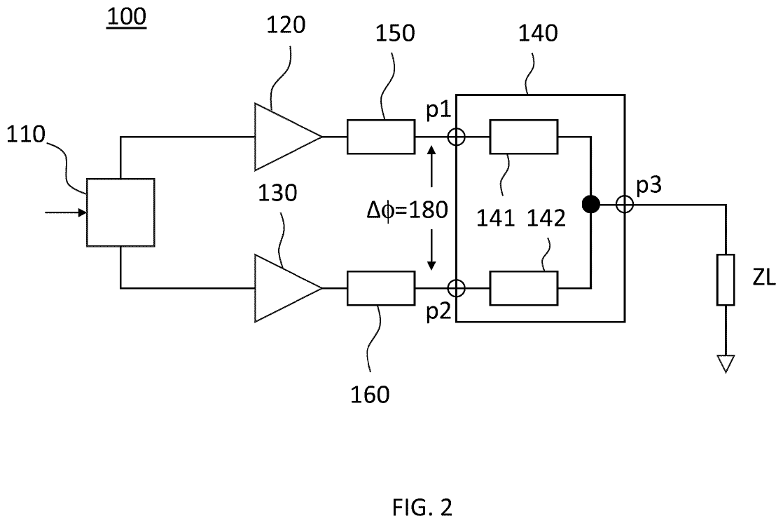

FIG. 2 illustrates a general embodiment of a DPA 100 in accordance with the present disclosure. DPA 100 comprises a splitter 110 for splitting an input signal, a main amplifier 120, a peak amplifier 130, a non-impedance-inverting network 150, a first impedance inverting network 160, and a Doherty combiner 140.

Main amplifier 120 and peak amplifier 130 can be matched devices. For example, main amplifier 120 and peak amplifier 130 can be each be matched to an impedance Zm for outputting saturated power.

Doherty combiner 140 comprises a second impedance inverting network 141 in between ports p1 and p3, and a third impedance inverting network 142 arranged in between ports p2 and p3. The output of DPA 100, corresponding to port p3, is connected to a load impedance ZL. This latter impedance may correspond to a series connection of an impedance matching network, e.g., a quarter wavelength transmission line, and an actual load, e.g., 50 Ohm.

Within the content of the present disclosure, an inverting network has an electrical length, at or close to the operational frequency, of (2n+1)×90 degrees, with n being an integer number different from 0.

According to the present disclosure, signals at ports p1 and p2 have opposite phases. More specifically, a phase difference of about 180 degrees exists between these signals at or close to the operational frequency. To achieve the 180 degrees phase offset, splitter 110 may add a 90 degrees delay for signals provided to peak amplifier 130 relative to signals provided to main amplifier 120.

Under power back-off, peak amplifier 130 will be switched off. As the electrical length between the output of peak amplifier 130 and port p3 is a multiple of 180 degrees, no or little impedance inversion will take place and a high impedance can be seen at port p3 looking towards peak amplifier 130. Furthermore, under these conditions less current will be output through port p3 than in saturated power conditions. The effective impedance seen looking towards port p3, e.g., downstream of second impedance inverting network 141, will be less than in saturated power conditions. Due to the combination of non-impedance-inverting network 150 and second impedance inverting network 141, this lower impedance will be inverted to a higher impedance seen at the output of main amplifier 120. Consequently, a high efficiency can be obtained under power back-off.

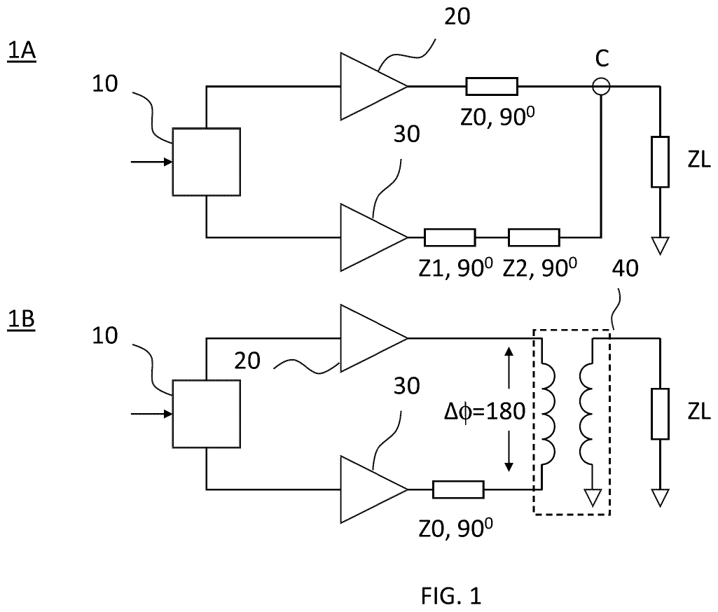

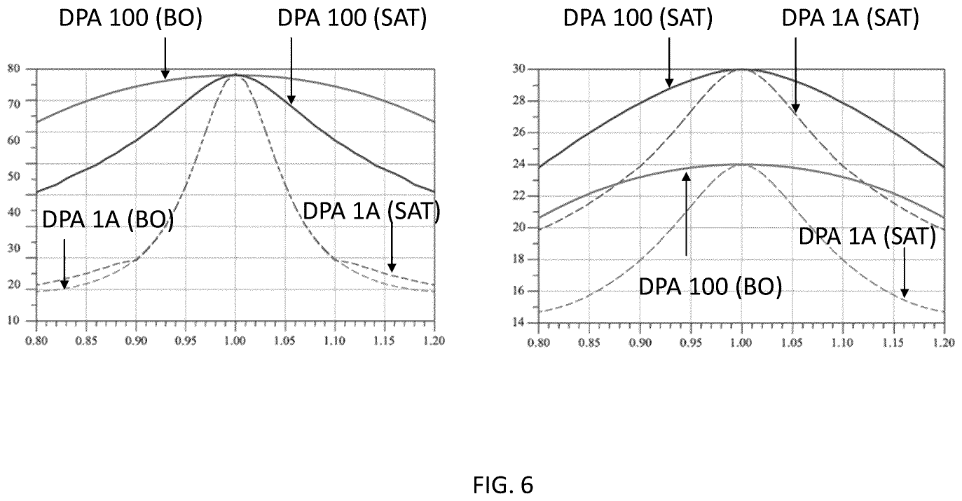

FIG. 6 illustrates a comparison between DPA 100 and known DPA 1A shown in FIG. 1. The figure on the left illustrates the efficiency as a function of frequency in GHz for back-off (BO) and saturated power (SAT) conditions. The figure on the right illustrates the output power in dBm as a function of frequency in GHz. As shown, DPA 100 offers a greater bandwidth than DPA 1A.

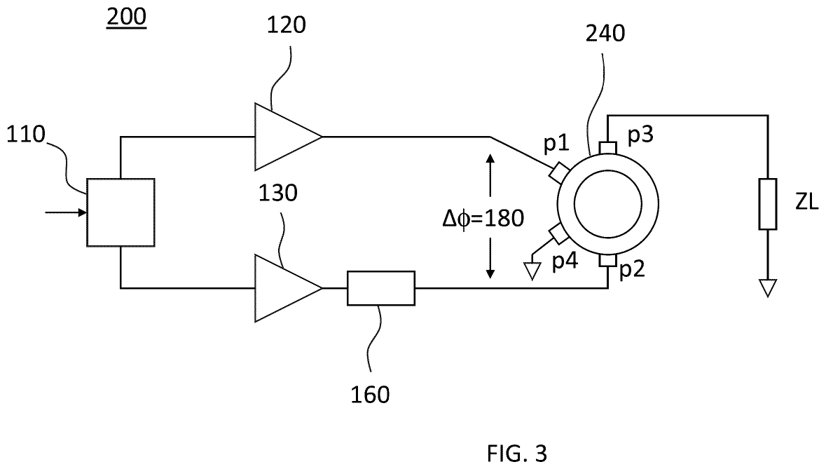

FIG. 3 illustrates a first specific embodiment of DPA 100. More in particular, DPA 200 comprises a rat-race coupler 240 that embodies Doherty combiner 140 of DPA 100. In addition, non-impedance-inverting network 150 is replaced by a through having an electrical length equal to n×360 degrees, with n being an integer, wherein n may be zero. Impedance inverting network 160 is embodied using a single 90 degrees transmission line.

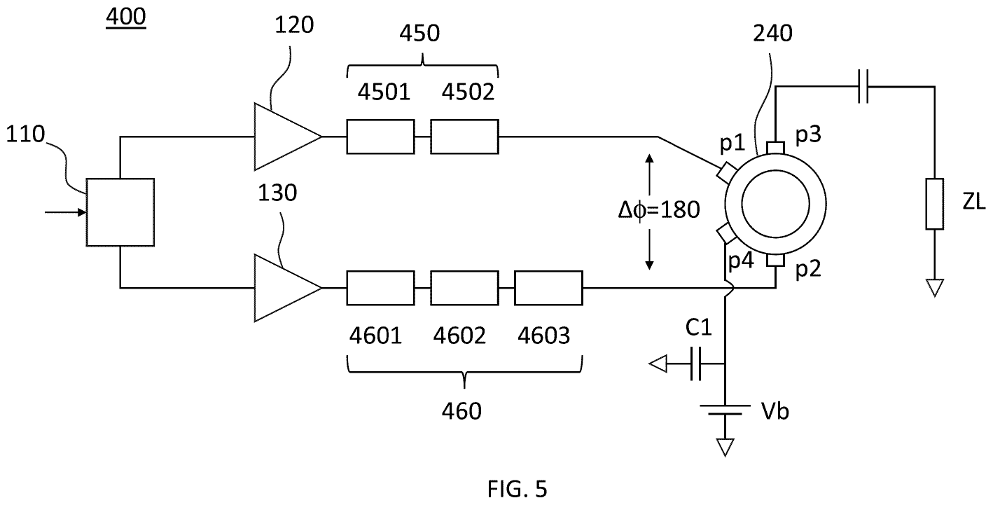

An electrical length between ports p1 and p3 equals 90 degrees, whereas the electrical length between ports p2 and p3 equals 270 degrees. Port p4 is RF grounded. As ports p1 and p4 and ports p1 and p2 are separated by an electrical length of 90 degrees, the RF short is transferred to an RF open at ports p1 and p2. This aspect allows port p4 to be used as bias access point. This is shown in FIG. 5, where RF grounding is achieved using a capacitor C1 and a bias circuitry Vb is provided to bias peak amplifier 130 and mean amplifier 120. A DC blocking capacitor C2 is used to block DC signals from entering load impedance ZL.

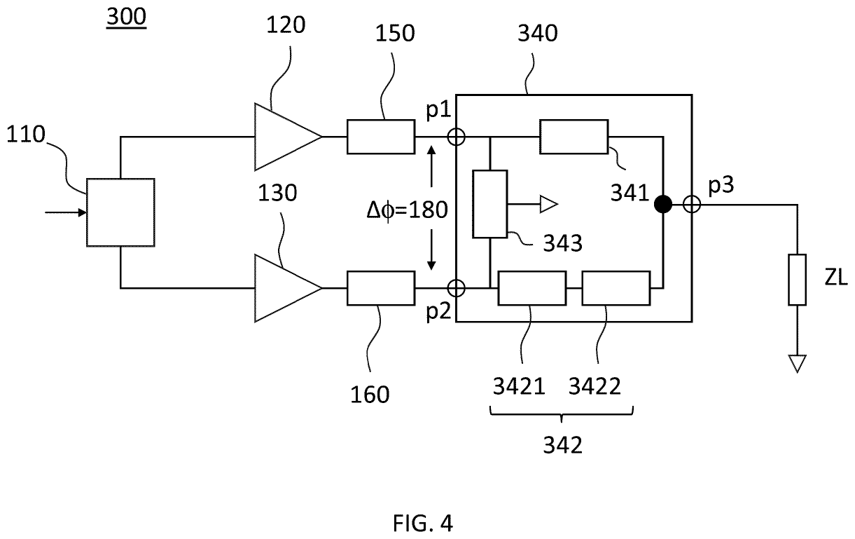

FIG. 4 illustrates a second specific embodiment of DPA 100. More in particular, DPA 300 comprises a Doherty combiner 340 which comprises a quarter wavelength transmission line between ports p1 and p3, and a series combination of a quarter wavelength transmission line and a half-wavelength transmission line in between ports p2 and p3. Similar to rat-race coupler 240, a half-wavelength transmission line is arranged in between ports p1 and p2, wherein the half-wavelength transmission line is RF grounded at a center region thereof.

FIG. 5 illustrates a further specific embodiment of DPA 100 in which a rat-race coupler 240 is used. In this case, non-impedance inverting network 450 comprises an impedance matching network 4501 and a transmission line 4502. Furthermore, main amplifier 120 and peak amplifier 130 are provided within a single package or as separate packages mounted on a printed circuit board, PCB. This same PCB can be used for realizing rat-race coupler 240 and/or any other transmission line based components of the embodiments shown in FIGS. 2-5. RF grounding of rat-race coupler 240 or of the center region of half wavelength transmission line 343 can be achieved using via technology or the like.

Main amplifier 120 can be formed using a semiconductor die mounted in a lead-frame package or other type of package. Typically, the drain of the power transistor that is realized on the semiconductor die is connected to a terminal of the package using some sort of electrical connection, such as one or more bondwires. These bondwires, as well as other package or device parasitics can be part of impedance matching network 4501. This latter network typically also comprises a part of a transmission line realized on the PCB, which part may partly serve as pad on which a terminal, such as a lead, of the package is mounted. The combination of impedance matching network 4501 and transmission line 4502 provides an electrical length that equals n×180 degrees at or close to the operational frequency. Moreover, in some embodiments, impedance matching network 4501 and transmission line 4502 both have electrical lengths that equal or at least approximate 90 degrees at or close to the operational frequency.

Similarly, peak amplifier 130 can be formed using a semiconductor die mounted in a lead-frame package or other type of package. In addition, first impedance inverting network 460 may comprise an impedance matching network 4601 and a pair of transmission lines 4602, 4603.

Impedance matching network 4601 may have a similar build-up as impedance matching network 4501. The combination of impedance matching network 4601, and transmission lines 4602, 4603 should provide an electrical length of (2n+1)×90 degrees, wherein n is an integer of 1 or larger.

For the embodiments shown in FIGS. 3, 4, 5, the transmission lines used in Doherty combiner 140, 240, 340, either as discrete lines or as part of the rat-race coupler, may all have the same characteristic impedance. This impedance may correspond to sqrt (2) times ZL. Under saturated power conditions, and assuming a power ratio of 1:1 between main amplifier 120 and peak amplifier 130, the effective impedance at port p3 seen from the main and peak branches, equals 2ZL. At port p1, this impedance is transformed by the second impedance inverting network to (sqrt(2)ZL)\hat{ }2/(2ZL)=ZL. The same impedance is seen at port p2. Furthermore, non-impedance-inverting network 150, and first impedance inverting network 160 ensure that this impedance is properly matched to the impedances required by main amplifier 120 and peak amplifier 130 to output saturated power.

It is noted that the example above, in which a power ratio of 1:1 was assumed, is but a mere example. The skilled person is well aware of how the various characteristic impedances must be chosen to account for different power ratios.

The description above presented details on embodiments in accordance with aspects of the present disclosure. However, the present disclosure is not limited to these embodiments. Rather, various modifications are possible without deviating from the scope of the present disclosure which is defined by the appended claims and their equivalents.

What is claimed is:

1. A Doherty amplifier, comprising:
a main amplifier;
a peak amplifier;
a Doherty splitter configured for:
splitting an input signal into a main signal part and a peak signal part; and
providing the main signal part and the peak signal part to the main amplifier and the peak amplifier, respectively;
a Doherty combiner having a first input port, a second input port, and an output port;
a non-impedance-inverting connection between an output of the main amplifier and the first input port; and
a first impedance inverting network arranged in between an output of the peak amplifier and the second input port,
wherein the Doherty splitter, the non-impedance-inverting connection, and the first impedance inverting network are configured such that a signal at the first input port of the Doherty combiner and a signal at the second input port of the Doherty combiner have opposite phases,
wherein the Doherty combiner comprises:
a second impedance inverting network in between the first input port and the output port; and
a third impedance inverting network in between the second input port and the output port, and
wherein the Doherty combiner is configured to add the signal amplified by the main amplifier and the signal amplified by the first amplifier in-phase at the output port.

2. The Doherty amplifier according to claim 1, wherein the second impedance inverting network comprises a transmission line or assembly of transmission lines having a first electrical length at the operational frequency, wherein the third impedance inverting network comprises a transmission line or assembly of transmission lines having a second electrical length at the operational frequency, and wherein the first electrical length and the second electrical length differ by substantially 180 degrees at the operational frequency.

3. The Doherty amplifier according to claim 2, wherein one of the second impedance inverting network and the third impedance inverting network comprises a quarter-wavelength transmission line, and wherein the other of the second impedance inverting network and the third impedance inverting network comprises a quarter-wavelength transmission line in series with a half-wavelength transmission line.

4. The Doherty amplifier according to claim 3, wherein the Doherty combiner further comprises a second half-wavelength transmission line in between the first input and the second input of the Doherty combiner, and wherein a center region of the second half-wavelength transmission line is RF grounded.

5. The Doherty amplifier according to claim 4, wherein the half-wavelength transmission lines and the quarter-wavelength transmission lines of the second impedance inverting network and the third impedance inverting network jointly form a rat-race coupler.

6. The Doherty amplifier according to claim 4, further comprising a biasing circuitry for providing a bias signal to the main amplifier and the peak amplifier, wherein the biasing circuitry is connected to the center region of the second half-wavelength transmission line arranged between the first input and the second input of the Doherty combiner.

7. The Doherty amplifier according to claim 3, wherein the characteristic impedances of all the transmission lines of the second impedance inverting network and the third impedance inverting network are all equal to a same characteristic impedance.

8. The Doherty amplifier according to claim 1, wherein the first impedance inverting network comprises a first impedance matching network connected to the output of the peak amplifier, a first quarter-wavelength transmission line, and a second quarter-wavelength transmission line, and wherein the first quarter-wavelength transmission line is arranged between the first impedance matching network and the second quarter-wavelength transmission line.

9. The Doherty amplifier according to claim 8, wherein the peak amplifier comprises a peak power transistor having an intrinsic drain, and wherein the first impedance matching network is connected in between the intrinsic drain of the peak power transistor and the quarter-wavelength transmission line.

10. The Doherty amplifier according to claim 1, wherein the non-impedance-inverting connection comprises a second impedance matching network connected to the output of the main amplifier and a quarter-wavelength transmission line.

11. The Doherty amplifier according to claim 10, wherein the main amplifier comprises a main power transistor having an intrinsic drain, and wherein the second impedance matching network is connected in between the intrinsic drain of the main power transistor and the quarter-wavelength transmission line.

12. The Doherty amplifier according to claim 1, further comprising a printed circuit board, wherein the Doherty combiner is realized on the printed circuit board.

13. The Doherty amplifier according to claim 12, wherein the first impedance inverting network comprises a first impedance matching network connected to the output of the peak amplifier, a first quarter-wavelength transmission line, and a second quarter-wavelength transmission line, wherein the first quarter-wavelength transmission line is arranged between the first impedance matching network and the second quarter-wavelength transmission line, wherein the first quarter-wavelength transmission line and the second quarter-wavelength transmission line of the first impedance inverting network are realized on the printed circuit board, and wherein the first impedance matching network is partially realized on the printed circuit board.

14. The Doherty amplifier according to claim 13, wherein the non-impedance-inverting connection comprises a second impedance matching network connected to the output of the main amplifier and a quarter-wavelength transmission line, wherein the quarter-wavelength transmission line of the non-impedance-inverting connection is realized on the printed circuit board, and wherein the second impedance matching network is partially realized on the printed circuit board.

15. The Doherty amplifier according to claim 1, wherein the main amplifier and the peak amplifier are provided as packaged devices.

16. The Doherty amplifier according to claim 15, wherein the main amplifier and the peak amplifier are provided in a single package.

17. A base station for mobile telecommunications comprising the Doherty amplifier according to claim 1.
